(19) United States
(12) Patent Application Publication
(10) Pub. No.: US 2006/0203453 A1
(43) Pub. Date: Sep. 14, 2006

(54) Shielding structure

(76) Inventor: Yi Jen Chen, Taipei (TW)

Correspondence Address: BIRCH STEWART KOLASCH & BIRCH, PO BOX 747, FALLS CHURCH, VA, 22040-0747, US

(21) Appl. No.: 11/359,475

(22) Filed: Feb. 23, 2006

(30) Foreign Application Priority Data
Mar. 8, 2005 (TW) 094106937

(51) Int. Cl. H05K 7/20

(52) U.S. Cl. 361/704; 361/709

(57) ABSTRACT

A shielding structure for suppressing electromagnetic interference in a printed circuit board has at least a pad. A chip is disposed on the printed circuit board and a heat sink is disposed on the chip. The shielding structure includes a main body and a sidewall. In this case, the main body has a contacting portion and an opening. The contacting portion is in contact with the heat sink and one part of the heat sink protrudes from the main body via the opening. The sidewall is encircled around the main body. The sidewall is connected to the main body, has a connecting portion electrically connected to the pad. The main body, the sidewall, and the printed circuit board form a containing space, and the chip is disposed in the containing space.

### BACKGROUND OF THE INVENTION

1. Field of Invention

The invention relates to a shielding structure and, in particular, to a shielding structure for electromagnetic interference (EMI) suppression.

2. Related Art

The applications of power electronic circuits, such as switching power supplies, uninterruptible power supplies (UPS), and various power converters, have become more popular in the recent years. These circuits are often operating at high frequencies and, therefore, result in the electromagnetic interference (EMI) problem. Such high-frequency noises may interfere with normal operations of communication or other devices through electromagnetic radiation or wires. Consequently, countries all over the world have strict rules for the electromagnetic interference of electronic products.

Any circuit with an electric current is a potential source of the electromagnetic interference. When designing an electronic product, the electromagnetic compatibility has to be considered. The electromagnetic compatibility among various devices of the electronic product and the electromagnetic compatibility between the electronic product and other electronic devices in its environment have to pass muster. The obstacle between an emitting source and a receiving object is designed as a shielding for attenuating the interference strength.

Some electromagnetic interference sources may also be a heat source. In this case, the designs of heat dissipation and electromagnetic interference suppression have to be considered together. As shown in FIG. 1, a chip 12 is disposed on a printed circuit board (PCB) 11. In the prior art, heat-dissipating fins 13 are disposed on the chip 12 for dissipating heat. However, due to the antenna effect of the heat-dissipating fins 13, the electromagnetic interference becomes even more serious. Further, a metal shell 14 is usually used to enclose the chip 12, the heat dissipating fins 13, and the printed circuit board 11. Therefore, to solve the heat dissipation problem and the electromagnetic interference problem simultaneously, the costs in both design and material will be increased. Cost of the metal shell 14 is increased with the size of the printed circuit board 11.

However, not all the chips on the printed circuit board 11 will generate the electromagnetic interference. Thus, using the metal shell 14 to cover the entire printed circuit board 11 is impractical. How to use a simpler structural design to solve both the heat dissipation and the electromagnetic interference problems is an important subject to study.

### SUMMARY OF THE INVENTION

In view of the foregoing, the invention is to provide a shielding structure for simultaneously solving the heat dissipation problem and suppressing the electromagnetic interference.

To achieve the above, a shielding structure is provided for suppressing electromagnetic interference in a printed circuit board that has a pad. A chip is disposed on the printed circuit board and a heat sink is disposed on the main body has a contacting portion and an opening. The contacting portion is in contact with the heat sink and one part of the heat sink protrudes from the main body via the opening. The sidewall extends from the main body to surround the chip, and having a connecting portion electrically connected to the pad. The main body, the sidewall, and the printed circuit board define a containing space, and the chip is disposed in the containing space.

As described above, in the disclosed shielding structure, the main body, the sidewall, and the printed circuit board define the containing space enclosing the chip. Thus, the electromagnetic waves do not leak out.

To achieve the above, a shielding structure is used for suppressing electromagnetic interference in a printed circuit board. A chip is disposed on the printed circuit board. The printed circuit board has at least a pad. The shielding structure includes a main body and a heat sink. In this case, the main body has a connecting portion. A surface of the main body is in contact with the chip, and the connecting portion is electrically connected to the pad. The main body and the printed circuit board define a containing space, and the chip is disposed in the containing space. The heat sink is disposed on another surface of the main body.

As described above, the containing space is defined by the main body and the printed circuit board to accommodate the chip, thus the shielding structure can prevent electromagnetic interference. With one part of the main body in contact with the chip, the heat sink connecting to the main body can transfer the heat generated by the chip to the exterior.

### BRIEF DESCRIPTION OF THE DRAWINGS

The invention will become more fully understood from the detailed description given herein below illustration only, and thus is not limitative of the present invention, and wherein:

FIG. 1 is a schematic cross-sectional view of the conventional shielding structure;

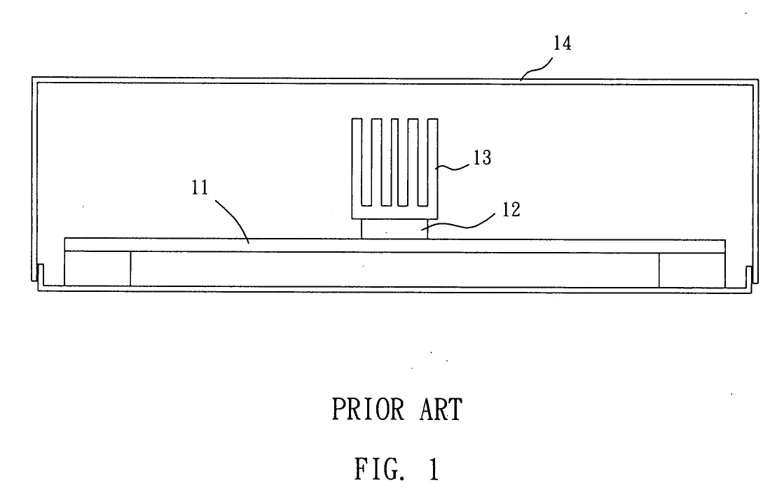

FIG. 2 is a schematic cross-sectional view of the shielding structure according to a preferred embodiment of the invention;

FIGS. 3A and 3B are schematic views of the shielding structure in FIG. 2;

FIG. 4 is a schematic cross-sectional view of another shielding structure according to the preferred embodiment of the invention; and

FIGS. 5A and 5B are schematic views of another shielding structure according to the preferred embodiment of the invention.

### DETAILED DESCRIPTION OF THE INVENTION

The present invention will be apparent from the following detailed description, which proceeds with reference to the accompanying drawings, wherein the same references relate to the same elements.

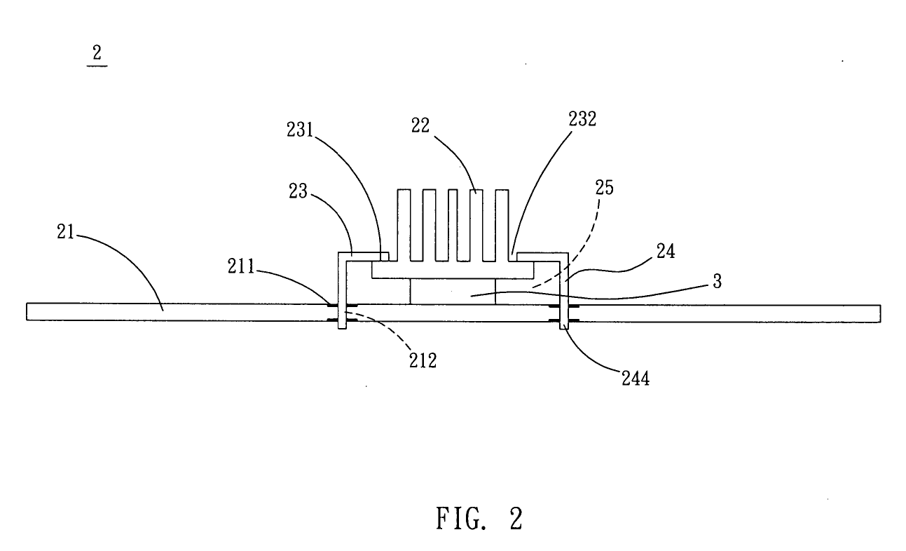

Please refer to FIG. 2, FIG. 2 is a schematic cross-sectional view of the shielding structure according to a preferred embodiment of the invention.

The shielding structure 2 according to the preferred embodiment of the invention is used for suppressing electromagnetic interference (EMI) in a printed circuit board (PCB) 21. A chip 3 is disposed on the printed circuit board 21, and a heat sink 22 is disposed on the chip 3. The printed circuit board 21 has pads 211. An embodiment of the disclosed shielding structure 2 includes a main body 23 and a sidewall 24.

The main body 23 has a contacting portion 231 in contact with the heat sink 22. The contacting portion 231 and the heat sink 22 are connected with a set of screws or by welding. Moreover, the heat sink 22 may include a set of heat dissipating fins.

One side of the sidewall 24 is connected to the main body 23, and the sidewall 24 is encircled around the main body 23. Another side of the sidewall 24 at least has a connecting portion 243, which is electrically connected to the pad 211. In this case, the main body 23, the sidewall 24, the heat sink 22, and the printed circuit board 21 form a containing space 25, and the chip 3 is disposed in the containing space 25.

The materials of the main body 23, the sidewall 24, and the heat sink 22 may be metals. In this embodiment, the materials of the main body 23 and the sidewall 24 may be tin, and the material of the heat sink 22 may be aluminum. Besides, the main body 23 further has an opening 232. One part of the heat sink 22 protrudes from the main body 23 via the opening 232. The heat generated by the chip 3 can be transferred to the exterior with the help of the heat sink 22. This is effective because the main body 23 and the sidewall 24 are both metals for transferring some heat to the environment.

In this embodiment, the printed circuit board 21 is provided with at least one solder hole 212 corresponding to the connecting portion 244. A pad 211 is formed around the solder hole 212. The connecting portion 244 is fixed in the solder hole 212 by reflow and is electrically connected to the pad 211. Since the heat sink 22 has an antenna effect, which may make the electromagnetic interference even worse, the pad 211 is connected to the ground so that the electromagnetic interference is transferred from the heat sink 22 to the ground via the contacting portion 231, the main body 23, the sidewall 24, and the connecting portion 244. This can attenuate the electromagnetic interference caused by the antenna effect. Moreover, if the materials of the main body 23 and the sidewall 24 are not metals, their surfaces can be sprayed with a conductive gel or sputtered with a metal layer. The conductive gel or the metal layer is then electrically connected to the pad 211, so that the electromagnetic interference is transferred from the heat sink 22 to the ground via the contacting portion 231, the main body 23, the sidewall 24, and the connecting portion 244.

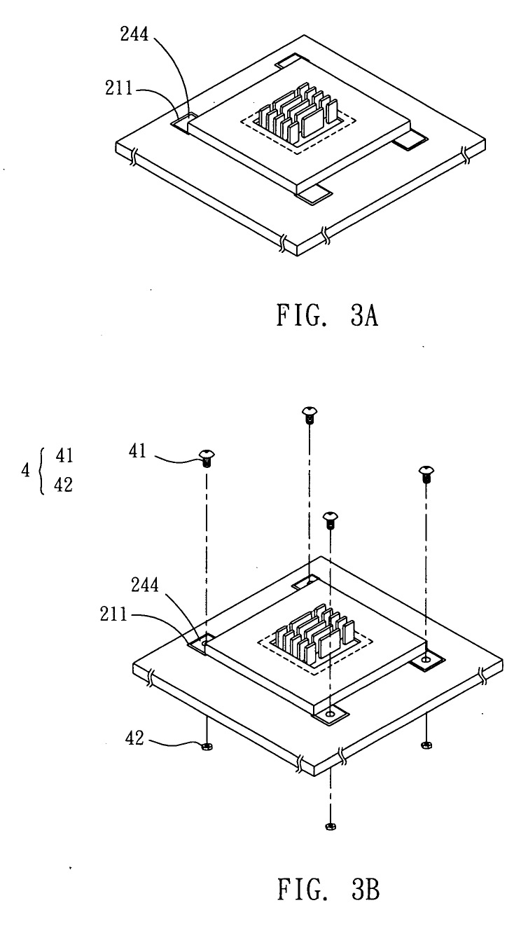

As shown in FIG. 3A, the connecting portion 244 can also be disposed on the pad 211 using the surface mounted technology (SMT). Alternatively, as shown in FIG. 3B, the connecting portion 244 may also be fixed on the pad 211 using a fastening element 4. Herein, the fastening element 4 may consist of a screw 41 and a nut 42.

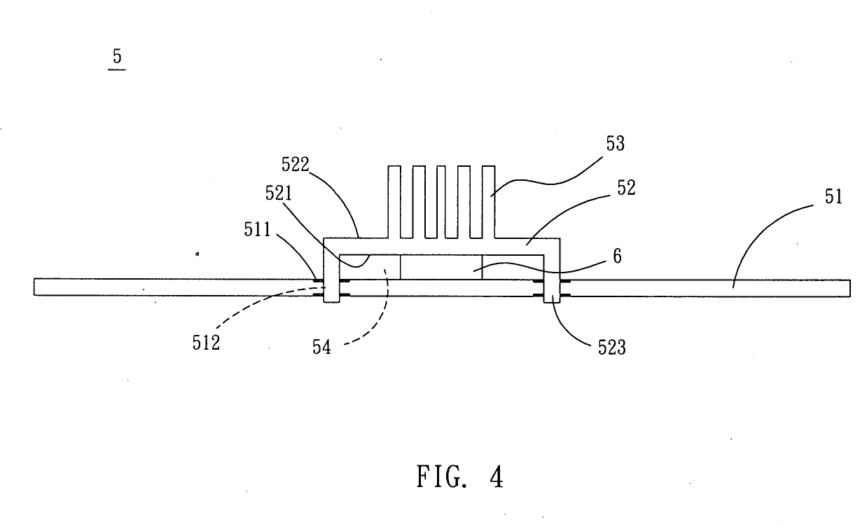

With reference to FIG. 4, another shielding structure 5 according to the preferred embodiment of the invention includes a printed circuit board 51, a main body 52, and a heat sink 53. A chip 6 is disposed on the printed circuit board 51, and the printed circuit board 51 has at least one pad 511. The materials of the main body 52 and the heat sink 53 may be metals. In this embodiment, the materials of the main body 52 and the heat sink 53 are aluminum or tin.

The main body 52 has a first surface 521, a second surface 522, and a connecting portion 523. The first surface 521 is in contact with the chip 6. The connecting portion 523 is electrically connected to the pad 511. The main body 52 and the printed circuit board 51 form a containing space 54. In this embodiment, the chip 6 is disposed in the containing space 54.

The heat sink 53 is disposed on the second surface 522 of the main body 52 to transfer the heat generated by the chip 6 to the environment via the main body 52 and heat sink 53. In this embodiment, the heat sink 53 may include a set of heat-dissipating fins and may be integrally formed with the main body 52.

In this embodiment, the printed circuit board 51 is formed with at least one solder hole 512 corresponding to the connecting portion 523. A pad 511 is then formed around the solder hole 512. The connecting portion 523 is fixed in the solder hole 512 by reflow and is electrically connected to the pad 511. Since the structure of the heat sink 53 may produce the antenna effect, the electromagnetic interference may become more serious. Therefore, the pad 511 may be connected to the ground so that the electromagnetic interference is transferred from the heat sink 53 to the ground via the main body 52 and the connecting portion 523. This can attenuate the electromagnetic interference caused by the antenna effect.

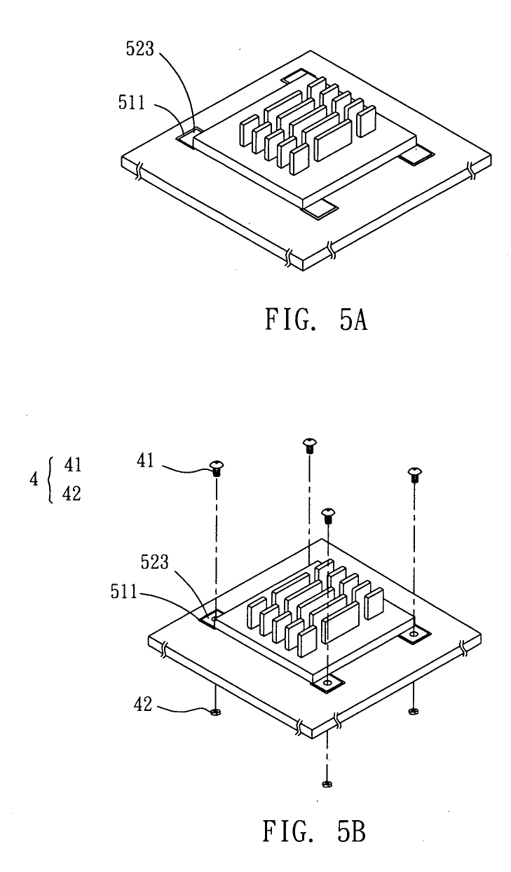

With reference to FIG. 5A, the connecting portion 523 may also be disposed on the pad 511 using the surface mounted technology. Alternatively, as shown in FIG. 5B, the connecting portion 523 may be fixed on the pad 511 using a fastening element 4. The fastening element 4 may consist of a screw 41 and a nut 42.

A further shielding structure of the preferred embodiment includes a heat sink and a main body.

The chip, the heat sink, and the main body mentioned in the following embodiment have the equivalent features and materials as the previously mentioned embodiments. Therefore, we do not address on these issue herein, but emphasize on the structure.

The shielding structure is used for suppressing the electromagnetic interference in a printed circuit board. A chip is disposed on the printed circuit board with at least one pad. The main body has a contacting portion and a sidewall. The contacting portion is in contact with the heat sink. One side of the sidewall is connected to the main body, and the sidewall is encircled around the main body. Another side of the sidewall at least has a connecting portion electrically connected to the pad. The main body and the printed circuit board form a containing space for accommodating the chip.

In summary, the disclosed shielding structure takes the heat sink for heat dissipation in the prior art into account. By forming a containing space with the heat sink, the main body, and the printed circuit board, the material cost is greatly saved in comparison with the prior art that uses a metal shell to enclose the printed circuit board and the heat sink. Although the heat sink produces the antenna effect to make the electromagnetic interference more serious due to its structure, the invention connects the connecting portion with the pad of the printed circuit board, which is connected to the ground, to transfer the electromagnetic interference produced by the heat sink to the ground via the main body and the connecting portion. As a result, the heat generated by the chip is transferred to the environment, while the electromagnetic interference is effectively suppressed as well. The invention can achieve the effects of reducing the product volume, lowering the material cost, suppressing the electromagnetic interference, and dissipating the heat.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A shielding structure for suppressing electromagnetic interference in a printed circuit board on which a chip is disposed, the printed circuit board having a pad, a heat sink disposed on the chip, the shielding structure comprising:
a main body having a contacting portion and an opening, the contacting portion contacting with the heat sink, one part of the heat sink protruding pass through the main body via the opening; and
a sidewall, extending from the main body to surround the chip, and having a connecting portion electrically connected to the pad.

2. The shielding structure of claim 1, wherein the connecting portion is disposed on the pad by surface mounting technology (SMT).

3. The shielding structure of claim 1, wherein the connecting portion is fixed on the pad by reflow.

4. The shielding structure of claim 1, wherein the connecting portion is fixed on the pad using a fastening element.

5. The shielding structure of claim 1, wherein the material of the main body is selected from the group consisting of aluminum and tin.

6. The shielding structure of claim 1, wherein the material of the sidewall is selected from the group consisting of aluminum and tin.

7. A shielding structure for suppressing electromagnetic interference in a printed circuit board on which a chip is disposed, the printed circuit board having at least a pad, the shielding structure comprising:
a main body having a connecting portion, wherein the surface of the main body is in contact with the chip, the connecting portion is electrically connected to the pad, the main body and the printed circuit board define a containing space, the chip is disposed in the containing space; and
a heat sink, which is disposed on another surface of the main body.

8. The shielding structure of claim 7, wherein the material of the main body is selected from the group consisting of aluminum and tin.

9. The shielding structure of claim 7, wherein the material of the heat sink is selected from the group consisting of aluminum and tin.

10. The shielding structure of claim 7, wherein the connecting portion is fixed on the pad by surface mounting technology.

11. The shielding structure of claim 7, wherein the connecting portion is fixed on the pad by reflow.

12. The shielding structure of claim 7, wherein the connecting portion is fixed on the pad using a fastening element.

13. The shielding structure of claim 7, wherein the heat sink comprises at least a heat dissipating fin.

14. The shielding structure of claim 7, wherein the main body is integrally formed with the heat sink.

15. The shielding structure of claim 14, wherein the materials of the main body and the heat sink are selected from the group consisting of aluminum and tin.
